(19) United States
(12) Patent Application Publication
(10) Pub. No.: US 2007/0181192 A1
(43) Pub. Date: Aug. 9, 2007

(54) Method and apparatus for monitoring gas flow amount in semiconductor manufacturing equipment

(76) Inventors: Sang-Kook Choi, Suwon-si (KR); Chang-Hyun Lim, Suwon-si (KR); Young-Sang Lee, Seoul (KR); Nam-Oh Kim, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/546,317

(22) Filed: Oct. 12, 2006

(30) Foreign Application Priority Data
Feb. 6, 2006 (KR) 2006-0011257

(51) Int. Cl. H01L 21/66; G01M 3/26; G01F 1/00

(52) U.S. Cl. 137/551; 73/198; 73/40; 438/5; 438/12; 340/605; 340/606

(57) ABSTRACT

An apparatus for monitoring gas flow in a semiconductor manufacturing equipment, includes an exhaust line, a flow amount measuring unit, and a controller unit having a first input electrically connected to the flow amount measuring unit and a second input having a predetermined reference value, the controller unit having the capability of comparing data in the first input to the predetermined reference value in the second input and generate a signal when the data in the first input exceed the predetermined reference value. The apparatus of the present invention may be incorporated into a gas delivery system employed in semiconductor manufacturing to detect gas leaks.

### BACKGROUND OF THE INVENTION

1. Field of the Invention

The present invention relates to semiconductor manufacturing equipment. In particular, the present invention relates to semiconductor manufacturing equipment having an improved gas delivery system with a flow monitoring apparatus capable of detecting leaks.

2. Description of the Related Art

In general, manufacturing of semiconductor devices may require multiple-step wafer processing, such as photographic processing, etching, diffusion, chemical vapor deposition (CVD), ion implantation, metal deposition, and so forth. In processing steps such as, for example, etching, diffusion and CVD, a gas delivery system may be required for treating wafers with gas under predetermined constant pressure conditions, e.g., vacuum.

Treatment of a wafer with gas may include placement of the wafer in a pressure-controlled process chamber, where gas may be supplied to interact with the wafer. When the gas includes more than one constituent gas, the constituent gases may be pre-mixed prior to entering the process chamber, e.g., dry etching, or post-mixed in the process chamber according to the required wafer treatment. The pressure in the process chamber may be kept constant; however, each constituent gas may have its own partial pressure in accordance with the wafer processing specifications. Once the treatment of the wafer is complete, the process chamber may be purged to remove any remaining gas. Accordingly, wafer treatment may require a gas delivery system having a mechanism for supplying gas and a mechanism for removing any residual gas remaining in the process chamber after the wafer treatment is complete.

During operation of a gas delivery system, the amount of gas entering a process chamber may be monitored to provide a good quality semiconductor. The gas amount may depend on the density of the gas, the reactivity of the wafer surface, and the reaction rate of the gas on the wafer surface. Imprecise gas amount may result in a defective semiconductor. For example, in etching, diffusion, oxidation and/or CVD processing, an excess of gas flow amount and/or time may result in a film that is thicker than necessary. Similarly, an insufficient gas flow amount and/or time may result in insufficient wafer treatment or film coverage. Either type of imprecision may impair the physical and/or electrical properties of the wafer, thereby impairing the functioning of the corresponding electrical circuit.

Accordingly, any factors that may impair gas flow monitoring in a gas delivery system, e.g., unknown leakage of gas, such as direct or indirect atmospheric air flow into the process chamber, may be unfavorable in semiconductor manufacturing, because it may trigger impaired wafers and defective products.

Therefore, there exists a need for semiconductor manufacturing equipment that would include a gas delivery system having improved monitoring capabilities of gas flow amounts to provide a precise detection system for excess gas flow or leakage.

### SUMMARY OF THE INVENTION

The present invention is therefore directed to a gas delivery system of semiconductor manufacturing equipment, which substantially overcomes one or more of the problems due to the limitations and disadvantages of the related art.

It is therefore a feature of an embodiment of the present invention to provide an improved gas delivery system having a gas flow amount monitoring apparatus for detecting gas leaks. At least one of the above and other features and advantages of the present invention may be realized by providing an apparatus for monitoring gas flow in a semiconductor manufacturing equipment, including an exhaust line, a flow amount measuring unit, and a controller unit including a first input electrically connected to the flow amount measuring unit and a second input having a predetermined reference value, the controller unit having the capability of comparing data in the first input to the predetermined reference value in the second input. The apparatus may also include an alarm unit electrically connected to the controller unit, while the flow amount measuring unit may be a mass flow meter.

The apparatus may also include a bypass line connected in parallel to the exhaust line and having a bypass valve. Additionally, the apparatus may also include an exhaust valve coupled to the exhaust line. The exhaust valve and the bypass valve may be in opposite states.

The flow amount measuring unit may be either in fluid communication with the exhaust line or in fluid communication with the bypass line and positioned downstream from the bypass valve. In another aspect of the present invention, there is provided a gas delivery system for semiconductor processing that includes at least one gas supplier, a process chamber, at least one supply line positioned between the gas supplier and the process chamber, the supply line including at least one main valve coupled to at least one gas flow controller, an exhaust line in fluid communication with the process chamber and including an exhaust valve positioned downstream on the exhaust line, and a flow amount measuring unit. The flow amount measuring unit may be in direct fluid communication with the exhaust line. The flow amount measuring unit may be a mass flow meter.

The gas delivery system may also include a bypass line connected in parallel to the exhaust line and having a bypass valve, such that the flow amount measuring unit is in fluid communication with the bypass line and positioned downstream from the bypass valve.

The gas delivery system may also include a controller unit electrically connected to the flow amount measuring unit. Additionally, the system may include an alarm unit electrically connected to the controller unit.

In yet another aspect of the present invention, there is provided a method for detecting gas leaks in semiconductor manufacturing equipment that includes advancing a predetermined amount of gas through a process chamber into an exhaust line, measuring the amount of gas flow in the exhaust line to obtain a measured amount of gas flow, comparing the predetermined amount of gas to the measured amount of gas flow, and determining a presence of a leak when the measured amount of gas flow exceeds the predetermined amount of gas.

Determining of a leak presence may include stopping the operation of semiconductor manufacturing. Determining of a leak presence may also include generating an alarm.

Measurement of gas flow amount in the exhaust line may include operating a mass flow meter.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a block diagram of a gas delivery system with an apparatus for detecting gas leaks according to an embodiment of the present invention; and

FIG. 2 illustrates a block diagram of gas delivery system with an apparatus for detecting gas leaks according to another embodiment of the present invention.

### DETAILED DESCRIPTION OF THE INVENTION

Korean Patent Application 10-2006-0011257, filed on Feb. 6, 2006, and entitled: “Method and Apparatus for Monitoring Mass Flow Amount in Semiconductor Manufacturing Equipment,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of elements and regions may be exaggerated for clarity of illustration. It will also be understood that when an element is referred to as being “on” another element or substrate, it can be directly on the other element or substrate, or intervening elements may also be present. Further, it will be understood that when an element is referred to as being “under” another element, it can be directly under, or one or more intervening elements may also be present. In addition, it will also be understood that when an element is referred to as being “between” two elements, it can be the only element between the two elements, or one or more intervening elements may also be present. Like reference numerals refer to like elements throughout.

Unless otherwise defined, all terminology used herein is given its ordinary meaning in the art, and therefore, should be interpreted within the context of the specification and the relevant art.

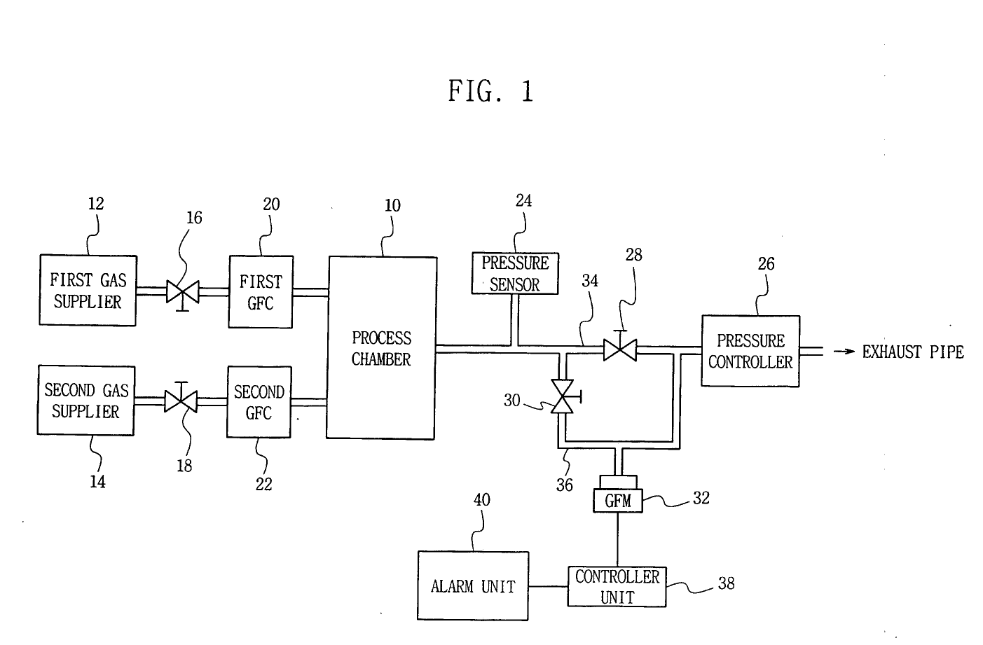

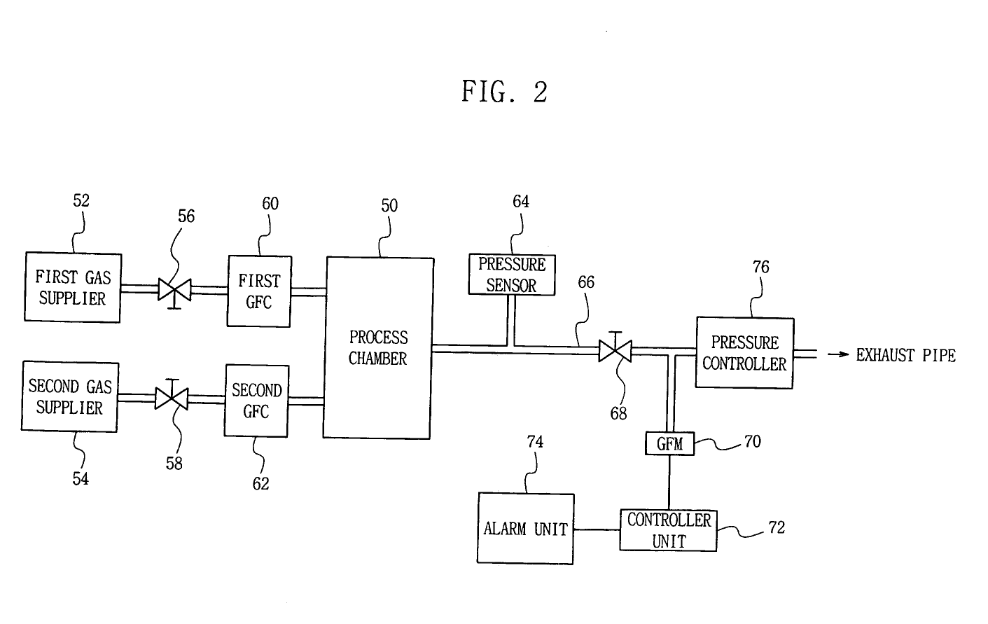

Exemplary embodiments of the present invention are more fully described below with reference to FIGS. 1 and 2. Both figures illustrate block diagrams of a gas delivery system having an apparatus for detecting gas leaks according to embodiments of the present invention.

As illustrated in FIG. 1, a gas delivery system according to the present invention may include a process chamber 10, a first gas supplier 12 to store a first gas, a second gas supplier 14 to store a second gas, a first main valve 16 to supply or cut off gas flow from the first gas supplier 12, a second main valve 18 to supply or cut off gas flow from the second gas supplier 14, a first gas flow controller (GFC) 20 to control the gas flow through the first main valve 16, a second GFC 22 to control the gas flow through the second main valve 18, a main exhaust line 34 to remove residual gas from the process chamber 10, a bypass line 36 to remove residual gas during leakage testing, a pressure sensor 24 to determine the pressure of gas removed from the process chamber 10, and an auto pressure controller (APC) 26 to control the pressure of the residual gas exiting process chamber 10. The pressure sensor 24 and APC 26 may be electrically connected.

The first and second GFCs 20 and 22 in the gas delivery system may be operated by a controller (not shown). The controller may apply voltage to the first and/or second GFC 20 and 22 to control the gas flow. For example, a maximum of about 5 V may be applied to the first and/or second GFC 20 and 22 to fully open them, and a minimum of about 0 V may be applied to the first and/or second GFC 20 and 22 to close them. The capacity of the first and second GFC 20 and 22 may be different for each gas and/or device. For example, the capacity may be from about 20 sccm to about 200 sccm.

Gas suppliers 12 and 14 may be storage tanks for storing gas to be used in the gas delivery system. The gas suppliers 12 and 14 may be connected to process chamber 10 via a supply line to transfer the stored gases into the process chamber 10. First and second valves 16 and 18, and first and second GFCs 20 and 22 may be installed on the gas supply line to control the gas flow entering the process chamber 10 from the first and second gas suppliers 12 and 14.

Process chamber 10 may be any type of vessel known by those skilled in the art for use in semiconductor processing. Process chamber 10 may be a pressure-controlled vessel having at least one inlet, preferably at least two inlets, and at least one outlet. The inlet(s) of process chamber 10 may be connected to the supply line, and the outlet of process chamber 10 may be connected to an exhaust pipe via the main exhaust line 34.

The main exhaust line 34 may have an exhaust valve 28 installed thereon to supply or discontinue residual gas flow through the main exhaust line 34. The main exhaust line 34 may also have a pressure sensor 24 installed thereon upstream from the exhaust valve 28, and an APC 26 installed thereon downstream from exhaust valve 28.

The bypass line 36 according to the present invention may be connected to the main exhaust line 34 in parallel, such that one end of bypass line 36 is connected upstream from the exhaust valve 28 and the other end from bypass line 36 is connected downstream of the exhaust valve 28. In other words, the bypass line 36 may function as a bypass loop around exhaust valve 28 to test the gas delivery system for leaks. In this regard, it should be noted that the connection points of main exhaust line 34 and bypass line 36 may be located between the exhaust valve 28 and pressure sensor 24 and between exhaust valve 28 and 26, respectively.

The bypass line 36 may also have installed thereon a bypass valve 30 to supply or discontinue residual gas flow. Exhaust valve 28 and bypass valve 30 may be any type of valves known to those skilled in the art, such as, for example, solenoids. The states of exhaust valve 28 and bypass valve 30 may be opposite, i.e., exhaust valve 28 may be open, when bypass valve 30 is closed, and vice versa.

The bypass line 36 may also have a flow amount measuring unit 32 (hereinafter referred to as gas flow meter or GFM) to measure the gas flow in bypass line 36, a controller unit 38 to receive gas flow data from the flow amount measuring unit 32 and, subsequently, generate an interlock signal when a leak is detected, and an alarm unit 40 to generate an alarm, e.g., sound alarm or other acceptable signal, when a leak is detected. The GFM 32, controller unit 38, and alarm unit 40 may be electrically connected.

The GFM 32 may be any flow measuring device known in the art such as, for example, a rotameter, a turbine meter, a mass flow meter (MFM), and any other device capable of measuring gas flow. Preferably, the flow amount measuring unit is a mass flow meter.

The controller unit 38 may include a first input electrically connected to the flow amount measuring unit such that it may receive the gas flow amount measured by the GFM 32. The controller unit 38 may also include a second input having a predetermined reference value. The predetermined reference value may be correlated to the amount of gas entering the process chamber 10 and/or the amount of gas being removed from the process chamber 10. The controller unit 38 may also include at least one output, such that the controller unit 38 may be capable of generating signals. The controller unit 38 may have the capability of comparing data in the first and second inputs.

In accordance with the present invention and with reference to FIG. 1, an exemplary method of operation of the inventive gas delivery system is as follows. A wafer may be place inside the processing chamber 10 and a vacuum pump (not shown) may be operated to provide a vacuum state within the process chamber 10, which thereinafter may remain hermetically sealed. Next, the first and second main valves 16 and 18 may be opened to allow gas flow from the first and second gas suppliers 12 and 14, respectively, e.g., argon and nitrogen, respectively, when the wafer is treated to form a layer of TiN. The amount of gas flow through the first and second main valves 16 and 18 may be controlled by the first and second GFCs 20 and 22, respectively. In this respect, it should be noted that the first and second main valves 16 and 18 may be closed when the gas supply line, the process chamber 10, the first GFC 20 or the second GFC 22 is undergoing maintenance or repair procedures, such as testing for leaks.

In the process chamber 10, the gas may be allowed to proceed and interact with the wafer, i.e., wafer treatment. After the wafer treatment is complete, the process chamber 10 may be purged to remove any remaining gases, e.g., residual gas, cleaning gas, unreacted gas, and so forth, through the main exhaust line 34. The removal of gas may be controlled by the pressure sensor 24 and APC 26. In particular, the pressure sensor 24 may detect and/or measure the pressure of the predetermined amount of gas removed from the process chamber 10 and, subsequently, transfer a signal to the APC 26. The APC 26 may control a pump (not shown) to maintain a predetermined pressure of the removed gas.

In this regard, it should be noted that the pressure sensor 24 and the APC 26 may control the pressure of a predetermined amount of gas removed from the process chamber 10; however, the pressure sensor 24 and APC 26 may have no control or measurement capabilities as to the actual amount of gas removed. Therefore, it is believed that the pressure sensor 24 may not effectively detect any excess gas, e.g. atmospheric air flow leaks, in the process chamber 10.

In accordance with the present invention, a testing loop may be provided for determining such leaks. In particular, the treatment of the wafer in the process chamber 10 may be paused, and the gas flow into and out of the process chamber 10 may be set to a predetermined amount to facilitate testing. In particular, when the treatment in process chamber 10 is paused, exhaust valve 28 may be closed and bypass valve 30 may be open to thereby divert gas flow exiting process chamber 10 through bypass valve 30 into bypass line 36. The gas flow exiting process chamber 10 may proceed through bypass line 36, such that the GFM 32, in fluid communication with bypass line 36, may measure the amount of gas exiting process chamber 10.

GFM 32 may transfer the date containing the measured amount of gas to the controller unit 38 via its first input, such that the controller unit 38 may compare the measured gas amount to a predetermined reference value. If the controller unit 38 determines that the measured gas amount exceeds the predetermined reference value, it may determine a leak. Consequently, the controller unit 38 may generate an interlock signal to stop the operation of the gas delivery system. Simultaneously, the controller unit 38 may transfer a signal to the alarm unit 40 to generate an alarm. If the controller unit 38 does not determined an excess gas amount, the operation of the gas delivery may proceed uninterrupted, i.e., the gas may proceed through bypass line 36 to main exhaust line 34 and APC 26, and the controller unit 38 may indicate (not shown) that the leak testing was successful.

For example, the gas flow into the process chamber 10 may be stopped completely, and subsequently, one of the main valves 16 or 18 may be opened to provide a predetermined amount of gas flow, e.g., about 1.00 cc, into the process chamber 10. When one of the main valves 16 or 18 provides a gas flow amount of about 1.00 cc into the process chamber, the predetermined reference value in the second input of the controller unit 38 may be set to about 1.00 cc as well. Next, the gas flow may proceed through exhaust valve 30 and bypass line 36, and the flow amount may be measured by the GFM 32. When GFM 32 transfers the data containing the measured gas flow amount to the controller unit 38, the controller unit 38 may compare the measured gas flow amount to the predetermined reference value of about 1.00 cc.

If the measured gas flow amount is, for example, about 1.10 cc, the controller unit 38 may detect an excess gas amount of about 0.10 cc, and subsequently, determine an air flow leak in the gas supply line or process chamber 10. Consequently, the controller unit 38 may generate simultaneous signals to stop the operation of the gas delivery system and generate an alarm.

A similar testing procedure may be implemented when the process chamber 10 is stopped completely and no gas flow in or out of the process chamber 10 may be detected. In this case, the predetermined reference value in the controller unit 38 may be set to about 0.00 cc, and when the controller unit 38 detects a gas flow amount measured by the GFM 32 that exceeds 0.00 cc, it may determine a leak. Similarly, the controller unit 38 may generate simultaneous signals to stop the operation of the gas delivery system and generate an alarm.

If the controller unit 38 does not detect excess gas in the measured gas flow amount, i.e., the measured gas flow amount does not exceed the reference value, the gas may proceed through bypass line 36 to main exhaust line 34 and APC 26, and the controller unit 38 may indicate (not shown) that the leak testing was successful.

In another embodiment of the present invention illustrated in FIG. 2, the gas delivery system may include a process chamber 50, a first gas supplier 52, a second gas supplier 54, a first main valve 56 to supply or cut off gas flow from the first gas supplier 52, a second main valve 58 to supply or cut off gas flow from the second gas supplier 54, a first gas flow controller GFC 60 to control the gas flow through the first main valve 56, a second GFC 62 to control the gas flow through the second main valve 58, an exhaust line 66 to remove residual gases from the process chamber 50, a pressure sensor 64 to sense pressure of removed gas, and an auto pressure controller (APC) 76 to control pressure of the residual gas exiting process chamber 50. The exhaust line 66 may have an exhaust valve 68 installed thereon to control or cut off residual gas flow.

The exhaust line 66 may also be in fluid communication with a flow measuring unit 70, e.g., gas flow meter (GFM), to measure the gas flow in the exhaust line 66, a controller unit 72, and an alarm unit 74.

It is noted that the particular elements included in the embodiment illustrated in FIG. 2 and their operation, as well as the overall method of operation of the gas delivery system, is similar to the description provided previously with respect to the gas delivery system illustrated in FIG. 1. Accordingly, only details that may be distinguishable from the previous embodiment will be described hereinafter. Details and descriptions that may be found in both embodiments of the gas delivery system illustrated in FIGS. 1-2 will not be repeated herein.

In accordance with the embodiment illustrated in FIG. 2, a GFM 70 may be placed in direct fluid communication with exhaust line 66 to detect gas leaks. The GFM 70 may be electrically connected to a controller unit 72 and an alarm unit 74, and the leakage testing procedure is performed as previously described with reference to FIG. 1. In particular, when the treatment in process chamber 50 is paused, a predetermined amount of gas flow enters process chamber 50, and a predetermined reference value is respectively set in controller unit 72. GFM 70 may measure the amount of gas flow passing through exhaust line 66 and transfer the measured value into the controller unit 72. The controller unit 72 may compare the measured value of the gas flow amount and the predetermined reference value. Determination of a measured value that exceeds the predetermined reference value may indicate a gas leak. For example, when a gas flow amount through the process chamber 50 is set to about 1.00 cc, a GFM 70 reading that exceeds the value of about 1.00 cc, e.g., 1.10 cc, may indicate an air leak. Consequently, the controller unit 72 may generate simultaneous signals to stop the operation of the gas delivery system and generate an alarm.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An apparatus for monitoring gas flow amount in a semiconductor manufacturing equipment, comprising:
an exhaust line;
a flow amount measuring unit; and
a controller unit including a first input electrically connected to the flow amount measuring unit and a second input having a predetermined reference value, the controller unit having the capability of comparing data in the first input to the predetermined reference value in the second input.

2. The apparatus as claimed in claim 1, further comprising an alarm unit electrically connected to the controller unit.

3. The apparatus as claimed in claim 1, wherein the flow amount measuring unit is in fluid communication with the exhaust line.

4. The apparatus as claimed in claim 1, further comprising a bypass line connected in parallel to the exhaust line and having a bypass valve.

5. The apparatus as claimed in claim 4, further comprising an exhaust valve coupled to the exhaust line.

6. The apparatus as claimed in claim 5, wherein the flow amount measuring unit is in fluid communication with the bypass line and positioned downstream from the bypass valve.

7. The apparatus as claimed in claim 5, wherein the exhaust valve and the bypass valve are in opposite states.

8. The apparatus as claimed in claim 1, wherein the flow amount measuring unit is a mass flow meter.

9. A gas delivery system for semiconductor processing, comprising:
at least one gas supplier;
a process chamber;
at least one supply line positioned between the gas supplier and the process chamber, the supply line including at least one main valve and at least one gas flow controller;
an exhaust line in fluid communication with the process chamber and including an exhaust valve positioned downstream thereof; and
a flow amount measuring unit.

10. The gas delivery system as claimed in claim 9, wherein the flow amount measuring unit is in direct fluid communication with the exhaust line.

11. The gas delivery system as claimed in claim 9, further comprising a bypass exhaust line connected in parallel to the exhaust line and having a bypass valve.

12. The gas delivery system as claimed in claim 11, wherein the flow amount measuring unit is in fluid communication with the bypass line and positioned downstream from the bypass valve.

13. The gas delivery system as claimed in claim 9, further comprising a controller unit electrically connected to the flow amount measuring unit.

14. The gas delivery system as claimed in claim 13, further comprising an alarm unit electrically connected to the controller unit.

15. The apparatus as claimed in claim 9, wherein the flow amount measuring unit is a mass flow meter.

16. A method for detecting gas leaks in semiconductor manufacturing equipment, comprising:
advancing a predetermined amount of gas through a process chamber into an exhaust line;
measuring the amount of gas flow in the exhaust line to obtain a measured amount of gas flow;
comparing the predetermined amount of gas to the measured amount of gas flow; and
determining a presence of a leak when the measured amount of gas flow exceeds the predetermined amount of gas.

17. The method as claimed in claim 16, wherein determining the presence of a leak comprises stopping the operation of semiconductor manufacturing.

18. The method as claimed in claim 16, wherein determining the presence of a leak comprises generating an alarm.

19. The method as claimed in claim 16, wherein measuring the amount of gas flow in the exhaust line includes operating a mass flow meter.
